(19) United States
(12) Patent Application Publication
(10) Pub. No.: US 2024/0219436 A1
(43) Pub. Date: Jul. 4, 2024

(54) DISAGGREGATION OF LOADS OF AN ELECTRICAL POWER SYSTEM

(71) Applicant: Schneider Electric USA, Inc., Andover, MA (US)

(72) Inventor: Brett E. Larson, Cedar Rapids, IA (US)

(73) Assignee: Schneider Electric USA, Inc., Boston, MA (US)

(21) Appl. No.: 18/125,825

(22) Filed: Mar. 24, 2023

Related U.S. Application Data
(60) Provisional application No. 63/436,189, filed on Dec. 30, 2022.

(51) Int. Cl. G01R 19/25; H02H 1/00; H02J 13/00

(52) U.S. Cl. CPC G01R 19/2513; H02H 1/0061; H02J 13/00002

(57) ABSTRACT

A disaggregation monitor is provided of an electrical power system having an electrical circuit with branches and loads. The disaggregation module includes a memory configured to store instructions and a processing device disposed at the location and in communication with the at least one memory. The processing device upon execution of the instructions is configured to a) iteratively and automatically control or instruct to turn ON one branch set having one or more branches of the plurality of branches at a time while remaining branches of the plurality of branches are turned OFF to isolate the branch set until all branches of the plurality of branches have been included in at least one isolated branch set, b) obtain an electrical signature of each isolated branch set; and c) disaggregate at least one load of the plurality of loads using two or more of the electrical signatures obtained.

### CROSS REFERENCE TO RELATED APPLICATIONS

This application claims priority to U.S. Provisional Patent Application Ser. No. 63/436,189 filed Dec. 30, 2022, which is incorporated herein by reference in its entirety.

### TECHNICAL FIELD

This disclosure relates to electrical power systems and methods, and more particularly to a system and method for disaggregation of loads of an electrical power system.

### BACKGROUND

Traditionally, load disaggregation is accomplished by a monitor that continuously monitors current and voltage at a main circuit breaker to learn more about individual loads on an electrical circuit controlled by the main circuit breaker. The monitor can fuse algorithms and machine learning and/or access these via cloud networking to determine recognizable characteristics of individual loads in time and frequency domains to determine when the individual loads are turned ON and OFF. Based on the monitored voltage and current, the monitor can use algorithms to calculate and/or estimate power usage that can be attributed to the respective individual loads while operating. Since there are can be multiple loads operating at the same time, the algorithms may take weeks or months to gather enough information to recognize an individual load in order to monitor that load over time. Usage of data from previously recognized loads from other connected monitors in other installations can help to facilitate the learning and recognition process over time.

The monitor can also attempt to identify a type of an individual load, such as refrigerator, washer, air conditioner, etc. The type can be used by the user to understand energy usage by a particular appliance. The monitor can use the type to give information and/or advice about how to make changes to reduce energy usage and/or about potential abnormal operation of the appliance.

While monitoring current and voltage at the main breaker can minimize a number of sensors used to monitor energy usage and loads, frequently most loads are not successfully disaggregated and/or categorized. These loads can be grouped into one category that may be labeled “Other” or “Always On”. These groups can be very large relative to groupings of successfully disaggregated and/or categorized loads, limiting potential benefits of the system to the user.

### SUMMARY

The purpose and advantages of the below described illustrated embodiments will be set forth in and apparent from the description that follows. Additional advantages of the illustrated embodiments will be realized and attained by the devices, systems and methods particularly pointed out in the written description and claims hereof, as well as from the appended drawings.

To achieve these and other advantages and in accordance with the purpose of the illustrated embodiments, in one aspect, disclosed is a disaggregation monitor of an electrical power system. The electrical power system has an electrical circuit that includes a plurality of branches and a plurality of loads. The disaggregation module includes at least one memory configured to store instructions and at least one processing device disposed at the location and in communication with the at least one memory. The at least one processing device upon execution of the instructions is configured to a) iteratively and automatically control or instruct to turn ON one branch set having one or more branches of the plurality of branches at a time while remaining branches of the plurality of branches are turned OFF to isolate the branch set until all branches of the plurality of branches have been included in at least one isolated branch set, b) obtain an electrical signature of each isolated branch set, and disaggregate at least two different loads of the plurality of loads using two or more of the electrical signatures obtained.

In one or more embodiments, the at least one processing device upon execution of the instructions can be further configured at a particular iteration of operation a) for a particular branch set that is isolated to: d) iteratively and automatically control or instruct to turn ON one load set of a second plurality of loads connected to the particular branch set at a time while remaining loads of the plurality of loads on the particular branch set that can be turned OFF are turned OFF to isolate the load set until all loads of the second plurality of loads have been included in at least one isolated load set, and e obtain an electrical signature of each isolated load set, wherein at c), the at least two different loads that are disaggregated include first and second loads of the second plurality of loads.

In one or more embodiments, the particular branch set can include one branch and/or the load set includes one load.

In one or more embodiments, a particular iteration of operation a) can be performed by automatically controlling to turn ON the isolated branch set and to turn OFF the remaining branches by controlling smart branch circuit breakers that correspond to respective branches of the plurality of branches.

In one or more embodiments, at least one processing device upon execution of the instructions can be further configured at operations b) and/or e) to obtain measurements from main sensors sensing line inputs to a main circuit breaker for the electrical circuit and/or obtain measurements at the isolated load set.

In one or more embodiments, at least one processing device upon execution of the instructions can be further configured at operations b) and/or e) to analyze electrical characteristics obtained from the main sensors and/or receive analysis of measurements obtained at the isolated load set for obtaining the electrical signature of each isolated branch set and/or load set.

In one or more embodiments, at least one processing device upon execution of the instructions can be further configured to use the electrical signatures of the isolated load sets to disaggregate and classify the respective isolated load sets.

In one or more embodiments, at least one processing device upon execution of the instructions can be further configured to determine a location of the respective isolated load sets and add the respective isolated load sets to a circuit mapping based on the corresponding location determined respective for the respective isolated sets.

In one or more embodiments, at least one processing device upon execution of the instructions can be further configured to operate one or more visual and/or audio indicators associated with one or more controllable loads of the second plurality of loads to provide a signal to a user regarding which load set of the electrical circuit is the isolated load set.

In one or more embodiments, at least one processing device upon execution of the instructions can be further configured to identify one or more loads of the second plurality of loads that were not successfully isolated in any of the isolated load sets or for which an disaggregated electrical signature was not successfully obtained, provide instructions to a user for manually isolating the respective identified one or more loads. At least one processing device upon execution of the instructions can be further configured to obtain disaggregated electrical signatures of the respective identified one or more loads after being manually isolated, attempt to classify the respective identified one or more loads based on each identified load's corresponding disaggregated electrical signature, determine a location of the respective identified one or more loads, and add the respective identified one or more loads to a circuit mapping using results of the attempt to classify and the location.

In one or more embodiments, at least one processing device upon execution of the instructions can be further configured to identify among the identified one or more loads a synchronized load and perform any combination of isolate, disaggregate, classify, and add to a circuit mapping individual loads included in the synchronized load.

In one or more embodiments, at least one processing device upon execution of the instructions can be further configured to identify among the identified one or more loads multiple loads of the plurality loads that belong to one complex load and classify and/or add to a circuit mapping the multiple loads as belonging to the complex load.

In one or more embodiments, at least one processing device upon execution of the instructions can be further configured to identify among the identified one or more loads a transient load, instruct a user to turn ON the transient load by operating the transient load at different operating states and/or at different locations of the electrical circuit, and obtain a disaggregated electrical signature of the transient load based on measurements obtained while operating the transient load at its different operating states and/or at the different locations or branch circuits.

In accordance with another aspect of the disclosure, a method is provided for performing disaggregation to a plurality of loads connected to a plurality of branches included in an electrical power system. The method includes iteratively and automatically controlling or instructing to turn ON one branch set having one or more branches of the plurality of branches at a time while remaining branches of the plurality of branches are turned OFF to isolate the branch set, obtaining a disaggregated electrical signature of each isolated branch set, and disaggregating at least one load of the plurality of loads using two or more of the electrical signatures obtained.

In one or more embodiments, for a particular iteration of automatically controlling or instructing to turn ON a particular branch set when the particular branch set is isolated, the method can further include Iteratively and automatically controlling or instructing to turn ON one load set of a second plurality of loads connected to the particular branch set at a time while remaining loads of the plurality of loads on the particular branch set that can be turned OFF are turned OFF to isolate the load set until all loads of the second plurality of loads have been included in at least one isolated load set, and obtaining an electrical signature of each isolated load set, wherein the at least two different loads that are disaggregated include first and second loads of the second plurality of loads.

In one or more embodiments, the method can further include using the electrical signatures of the isolated load sets to classify the respective isolated load sets.

In one or more embodiments, the method can further include determining a location of the respective isolated load sets and adding the respective isolated load sets to a circuit mapping based on the corresponding location determined for the respective isolated sets.

In one or more embodiments, the method can further include operating one or more visual and/or audio indicators associated with one or more controllable loads of the second plurality of loads to provide a signal to a user regarding which load set of the electrical circuit is the isolated load set.

In one or more embodiments, the method can further include identifying one or more loads of the second plurality of loads that were not successfully isolated in any of the isolated load sets or for which an disaggregated electrical signature was not successfully obtained, providing instructions to a user for manually isolating the respective identified one or more loads, obtaining disaggregated electrical signatures of the respective identified one or more loads after being manually isolated, attempting to classify the respective identified one or more loads based on each identified load's corresponding disaggregated electrical signature, determining a location of the respective identified one or more loads, and adding the respective identified one or more loads to a circuit mapping.

In accordance with still a further aspect of the disclosure, provided is a non-transitory computer readable medium having computer executable instructions configured to cause a computer to perform the disclosed method.

### BRIEF DESCRIPTION OF THE DRAWINGS

A more detailed description of the disclosure, briefly summarized above, may be had by reference to various embodiments, some of which are illustrated in the appended drawings. While the appended drawings illustrate select embodiments of this disclosure, these drawings are not to be considered limiting of its scope, for the disclosure may admit to other equally effective embodiments.

FIG. 1 is a schematic diagram of an example electrical power system including an electrical circuit, in accordance with embodiments of the disclosure;

FIG. 2 is a schematic diagram of an example load center of the electrical power system shown in FIG. 1, in accordance with embodiments of the disclosure

FIG. 3A is a flow diagram of an embodiment of an example method of fully automatically disaggregating controllable loads of a complex electrical circuit of an electrical power system, in accordance with embodiments of the disclosure;

FIG. 3B is a flow diagram of an embodiment of an example method of automatically disaggregating controllable loads of a complex electrical circuit, similar to the method shown in FIG. 3A, using automated recommendations for manual assistance, in accordance with embodiments of the disclosure; and

FIG. 4 is a block diagram of an example computer system used for implementation of a disaggregation monitor shown in FIG. 1, in accordance with embodiments of the invention.

Identical reference numerals have been used, where possible, to designate identical elements that are common to the figures. However, elements disclosed in one embodiment may be beneficially utilized on other embodiments without specific recitation.

### DETAILED DESCRIPTION

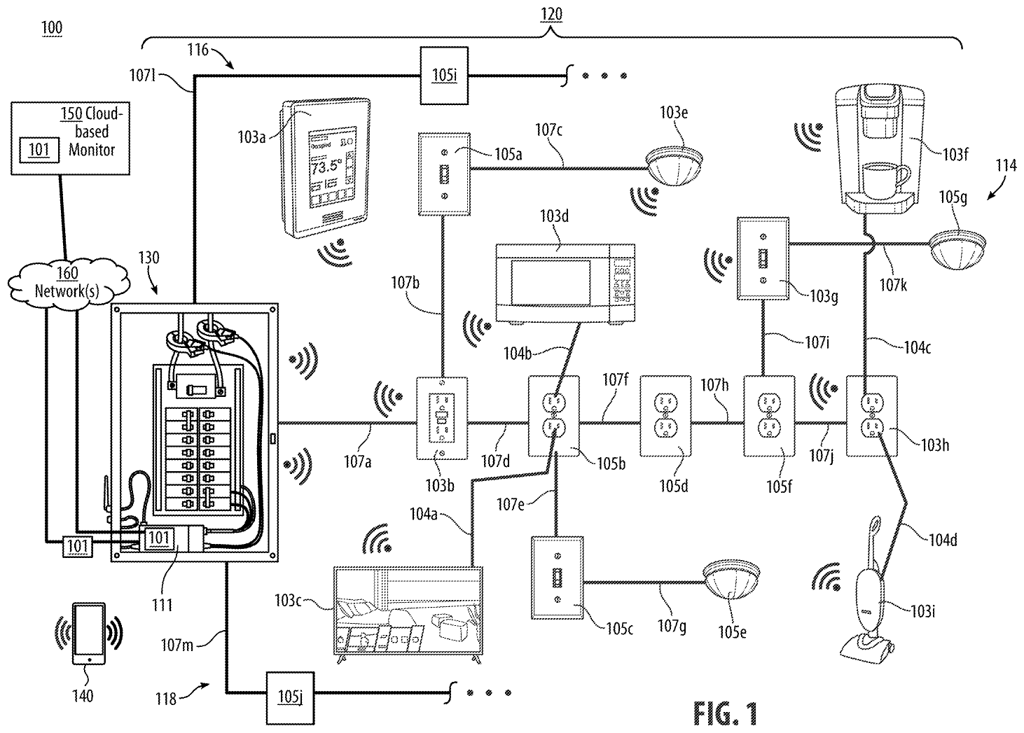

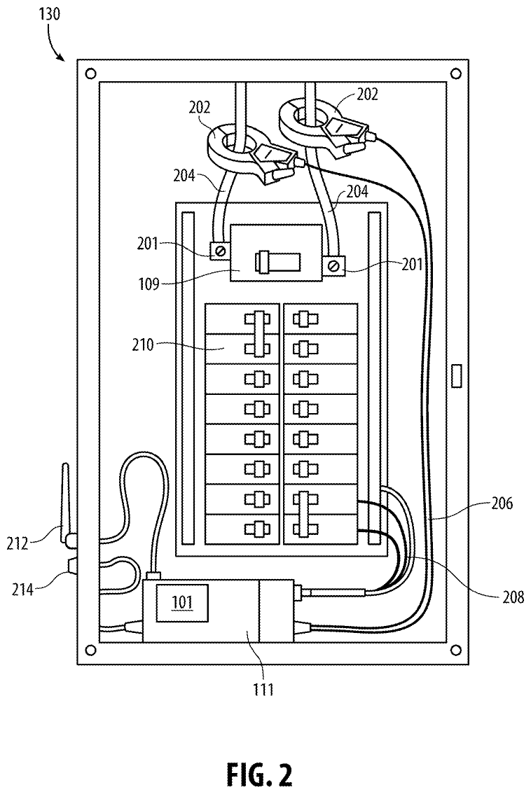

Reference will now be made to the drawings wherein like reference numerals identify similar structural features or aspects of the subject disclosure. For purposes of explanation and illustration, and not limitation, an illustrative view of an embodiment of an electrical power system in accordance with the disclosure is shown in FIG. 1 and is designated generally by reference character 100. Other embodiments and/or aspects of this disclosure are shown in FIGS. 2-4. Certain embodiments described herein can be used to perform a disaggregation process to disaggregate at least one load from a plurality of loads or at least one electrical branch from a plurality of electrical branches of electrical power system 100.

In accordance with at least one aspect of this disclosure, referring to FIG. 1, electrical power system 100 can include a disaggregation monitor 101 configured to isolate electrical signatures of one or more loads of a plurality of loads (for example, but not limited to loads 103a, b, c, d, e, f, g, h, i, 104a, b, c, d, 105a, b, c, d, e, f, g, h, i, j, 107a, b, c, d, e, f, g, h, i, j, k), or branches (or segments of the branches) of one or more branches of a plurality of branches (for example, but not limited to branches 114, 116, 118) of an electrical circuit 120. Additional or fewer loads and/or branches can be included in circuit 120.

Isolation is automatically performed by turning OFF and ON (by control and/or by instruction) different selected loads, selected branches, or selected segments of branches to iteratively isolate different branch sets (or segments), one at a time, of the plurality of branches 114, 116, 118 and/or to iteratively isolate different load sets, one at a time, of the plurality of loads 103a, b, c, d, e, f, g, h, i, 104a, b, c, d, 105a, b, c, d, e, f, g, h, i, j, 107a, b, c, d, e, f, g, h, i, j, k to learn an electrical signature associated with the respective isolated branch sets or load sets. The branch sets can include one or more branches and the load sets can include one or more loads. A branch segment can include a portion of a branch that is connected to a particular load, such as a switch, outlet or receptacle. The electrical signature of each isolated load set or branch set is attributable to that isolated load set or branch set.

An isolated branch set refers to a set of one or more of branches 114, 116, 118 that are turned ON while the remaining branches are turned OFF. An isolated load set refers to a set of one or more of loads 103a, b, c, d, e, f, g, h, i, 104a, b, c, d, 105a, b, c, d, e, f, g, h, i, j, 107a, b, c, d, e, f, g, h, i, j, k that are turned ON while the remaining loads are turned OFF.

In some embodiments, some non-controllable loads may remain ON during the disaggregation process (these loads can be referred to as always-ON loads), but the electric characteristics for the such loads can be identified and subtracted from electrical characteristics of branch set that is being (effectively) isolated by turning OFF remaining branches or load set that is being (effectively) isolated by turning OFF remaining loads on an isolated branch. As used herein, the term “load” includes ultimate loads (e.g., lights 103e, 105e, 105g and appliances 103a, 103c, 103d, 103f, 103i), circuit devices (e.g., switches 103g, 105a, 105c, outlets 103b, 103h, 105b, 105d, 105f), unspecified (not specified in the example) loads 105i and 105j, and connections (e.g., branch circuit wiring 107a, 107b, 107c, 107d, 107e, 107f, 107g, 107h, 107i, 107j, 107k, 107l, 107m and cord sets 104a, 104b, 104c, 104d) connecting the loads to the corresponding branch 114, 116, 118.

Each branch 114, 116, 118 can have connected to it one or more ultimate loads and one or more connections. Branches 114, 116, 118 can each include one or more sections, each section including a different subset of connections. For example branch 114 can include a first section 120a that includes branch circuit wiring 107a, 107b, and 107c, a second section 120b that includes branch circuit wiring 107a, 107d, 107e, and 107g, and a third section 120c that includes branch circuit wiring 107a, 107d, and 107f, 107h, 107i, 107k. Power to each branch 114, 116, 118 is controlled by respective branch circuit breakers 210, as described in FIG. 2. Disaggregation monitor 101 can communicate with the branch circuit breakers 210 to turn ON or OFF selected ones of the branch circuit breakers 210.

Disaggregation monitor 101 can include any suitable hardware and/or software module(s) configured to perform the disclosed functions. The disaggregation monitor 101 can be configured to be integrated with and/or in operative communication with components of a load center 130 described in FIG. 2. Communication with the components of load center 130 can be direct with the components or via an edge device 111. Edge device 111 can be integrated with load center 130 or remote from and in operative communication with load center 130. Additionally or alternatively, disaggregation monitor 101 can be in operative communication with one or more controllable loads, if any, of the plurality of loads 103a-i, 104a-d, 105a-j. In the example shown, loads 103a-i of the plurality of loads 103a-i, 104a-d, 105a-j are controllable loads. Disaggregation monitor 101 can communicate with controllable loads 130a-i to turn ON or OFF selected loads of controllable loads 103a-i, operate the selected load in a particular mode, and/or gather diagnostic information (e.g., make, model number, power consumption, alarms, etc.) The amount of diagnostic information may vary and increase in sophistication over time. The controllable loads 130a-i or a controllable circuit breaker that controls power to a branch 114, 116, or 118 or its segments can be controlled, for example, by controlling a power switch, relay, solid state switch, solenoid, or magnetic switch.

Disaggregation monitor 101 can communicate via wireless communication (e.g., via WiFi, ZigBee®, Bluetooth, cellular communication, near-field communication, or the like) and/or wired communication (e.g., via Ethernet, Modbus®, universal serial bus (USB), controller area network (CAN) bus, RS-232, RS-485, universal (synchronous/)asynchronous receiver-transmitter (USART/UART), or the like) communication, including via a network. Disaggregation monitor 101 can be disposed in one location or included in federated processing devices hosted on multiple devices that work together to embody the disaggregation monitor 101. The multiple devices can be disposed in more than one location, including local to load center 130 or remote from load center 130, e.g., connected to one or more networks 160 (e.g., a local area network (LAN) and/or a wide area network (WAN), such as the Internet). Disaggregation monitor 101 can be completely or partially located in a cloud-based monitor 101, meaning remotely connected via network(s) 160, wherein network(s) 160 include a LAN, such as the Internet. As such, all or a portion of processing performed by disaggregation monitor 101 can be performed remotely in the cloud.

Disaggregation monitor 101 can further communicate with a user device 140 having a user interface. The user interface can be configured to provide information to a user in a textual, audio, and/or graphical format, such as for providing instructions to a user to perform manual tasks, e.g., for connecting a load to a branch of the electrical power system 100, operating a load in different modes, or disconnecting selected loads of the plurality of loads 103a-i, 104a-d, 105a-j. The user interface can also be configured to receive information from a user, such as by prompting the user to input a command to enter a learning mode, name and identification of branches, information about a load (its location, make and model, etc.). In addition or alternatively to user device 140, a user interface can be integrated with other components, e.g., disaggregation monitor 101, edge device 111, and/or load center 130, without limitation. In one or more embodiments, the user interface is configured as a graphical user interface (GUI)

During a learning phase, the disaggregation monitor 101 can be configured to automatically control or instruct iterative turning OFF and/or turning ON of selected controllable loads 103a-i, branches 114, 116, 118, or sections of branches while maintaining power from main circuit breaker 109 to the remaining circuit 120 to monitor electrical characteristics. During the learning mode disaggregation monitor 101 can iteratively isolate each branch 114, 116, 118 (or branch segment) for obtaining measurements and/or electrical characteristics, and/or identifying electrical signatures of the isolated branch 114, 116, 118. The branches 114, 116, 118 can be isolated in sets of one or more branches at a time. Similarly, disaggregation monitor 101 can iteratively isolate each controllable load 103a-i (while disregarding always-ON loads) for obtaining measurements and/or electrical characteristics, and/or identifying electrical signatures of the isolated controllable load 103a-i. The controllable loads 103a-i can be isolated in sets of one or more controllable loads 103a-i at a time.

In one or more embodiments, disaggregation monitor 101 can be configured to automatically output instructions to a user interface module 113 for a user to manually power OFF and/or power ON one or more loads (e.g., manual switch 105c with light 105e downstream thereof) of the plurality of loads 103a-i, 104a-d, 105a-h to help isolate a particular load set, e.g., for monitoring electrical characteristics associated with the isolated load set. In certain embodiments, electrical circuit 120 may have no controllable loads and a user may be instructed to iteratively isolate load sets. Any suitable instructions are contemplated herein.

In certain embodiments, the disaggregation monitor 101 can be configured to automatically isolate (by control and/or by instructions to a user) subcomponents of a load (e.g., isolate a pump of a coffee machine, isolate a heater of the coffee machine) to monitor its associated electrical characteristics, such as to obtain an electrical signature of the subcomponents. Any other suitable disaggregation, analytical, and/or control function(s) for the disaggregation monitor 101 is contemplated herein for isolating portions (branch sets, load sets) of electrical circuit 120, obtaining associated electrical characteristics, learning associated electrical signatures, identifying associated load types, and/or learning associated locations in electrical circuit 120.

Disaggregation monitor 101 is configured to maintain state of connection data that indicates which branch set or load set of circuit 120 is isolated to be turned ON during each iteration of the learning phase. Disaggregation monitor 101 can continuously monitor the electrical characteristics sensed or obtained and/or the electrical signature determined and/or obtained, and correlate it with the state of connection data. The measurement data and/or electrical characteristics can be correlated to isolated the branch sets and/or load sets and analyzed by application of algorithms and machine learning (performed by disaggregation monitor 101 and/or controllable loads 103a, b, c, d, e, f, g, h, i). The analysis can determine electrical signatures, made of recognizable electrical characteristics in the time and/or frequency domain that can be attributed to the respective isolated branch sets and/or load sets for the purpose of disaggregating individual branches and loads or sets thereof.

When the correlation indicates that a controllable device (e.g., controllable ceiling lamp 103e) on a particular branch or branch segment (e.g., branch 114 or branch segment 107c) is ON only when that branch or branch segment is ON, then disaggregation monitor 101 can deduct that the controllable device is on that branch or branch segment. Thus, control of that controllable device can be used for performance of the disaggregation process.

Additionally, disaggregation monitor 101 can be configured to determine the type or location of an isolated load set. The type can be a fundamental load type (e.g., for a component of an appliance, such as a motor, resistive device, switch, power supply) or an appliance load type (e.g., refrigerator, clothes washer, oven. Identifying the load set's type is also referred to as classifying the load set. The location can be, for example, a room (e.g., kitchen, master bedroom, living room). This can be performed with or without the user input. User input can be automatically prompted to provide input and/or confirmation of a load type or location determined by disaggregation monitor 101. User input can be automatically requested while the load is isolated. The load set can be classified based on its electrical characteristics (e.g., of the corresponding isolated electrical signature) in the time and frequency domains. A load set can be, for example, a complex load, such as an appliance, that includes multiple fundamental loads, each fundamental load having a fundamental load type that operates in certain ways to provide the function of the appliance. The disaggregation monitor 101 may use interactions between electrical characteristics of these fundamental loads to classify the appliance.

Controllable loads 103a-i and/or or one or more locations on branches 114, 116, 118 may be provided with visual and/or audio indicators. These indicators can be integrated into respective individual controllable loads of the plurality of loads. For example the indicators can be a beeper of an oven timer of a clothes dryer to indicate completion of a drying cycle, a light installed in branch circuit wiring, a light of a lighting device, etc. Disaggregation monitor 101 can control the indicators by way of its ability to control the controllable load. The visual and/or audio indicators can be automatically operated by disaggregation monitor 101 to signal to the user when and where a manual action is needed for user participation in the isolation and/or classification processes and for the mapping of the controllable loads 103a-i on electrical circuit 120.

A system monitor can calculate and/or estimate power usage that can be attributed to individual or groups of loads or branches from voltage and current measurements attributed to these while operating (i.e., turned ON). The system monitor can be integrated with disaggregation monitor 101, edge device 111, user device 140, or provided separately therefrom. Furthermore, this information can be processed to analyze energy usage per appliance, such as to provide information or advice on how to reduce energy usage or about potential abnormal operation of the appliance. Any of this information can be provided to the user via the user interface and/or incorporated into a report provided to the user.

By iterating the automated isolation process to attempt to isolate load sets one at a time, disaggregation monitor 101 can disaggregate the plurality of loads 103a-i, 104a-d, 105a-j into separate loads or load sets. The disaggregation process for separating the loads includes identifying and learning about electrical characteristics and electrical signatures of the isolated load sets. This knowledge is used to identify electrical signatures of as many of the loads of the plurality of loads 103a-i, 104a-d, 105a-j as best as possible in order to disaggregate the corresponding loads. Location information associated with the isolated load sets can be used to generate a circuit mapping. The circuit mapping includes location and/or classification (and possibly identification of different load sets having the same classification) of the disaggregated loads of the plurality of loads 103a-i, 104a-d, 105a-j. The location of a load set can identify the branch or branch segment to which the load set is connected.

As described further, an automated manual assist mode can be used to supplement the disaggregation and circuit mapping process to further automatically isolate, separate, classify, and map loads of the plurality of loads 103a-i, 104a-d, 105a-j that are not controllable and were not successfully disaggregated, classified, and/or mapped, thus further completing the circuit mapping. The disaggregation and circuit mapping process can use only control of controllable loads 103a-i and branches (of branches 114, 116, 118), only instruction for operating non-controllable loads 104a-d, 105a-j or branches (of branches 114, 116, 110), or any combination of the two.

With additional reference to FIG. 2, a load center 130 is shown. Disaggregation monitor 101 is shown integrated (e.g., sharing a housing, circuits and/or more) with edge device 111, although disaggregation monitor 101 can alternatively or additionally be provided next to or remote from edge device and/or load center 130. Edge device 111 is installed in load center 200, but can alternatively can be provided next to or remote from load center 130.

Main circuit breaker 109 and a plurality of branch circuit breakers 210 are disposed in load center 130. Main circuit breaker 109 is connected at line connectors 201 to line cables 204. Main circuit breaker 109 is configured to selectively break the connection between circuit 120 and line cables 204. Line cables 204 provide line power from an external source to circuit 120. Each branch circuit breaker 210 is connected to one branch of circuit 120 (e.g., branches 114, 116, and 118). Branch circuit breakers 210 receive a portion of the line power and deliver and guide an appropriate current to its corresponding branch and to one or more of the plurality of loads 103a-i, 104a-d, 105a-j that are connected to the branch and demand power. Each branch circuit breaker 210 is further configured to break a connection by which power is delivered to its corresponding branch.

Main circuit breaker 109 and/or one or more of branch circuit breakers 210 can be a smart function breaker configured to receive, process, and/or output data, to be controlled, and/or to control another device. It follows that main circuit breaker 109 and/or one or more of branch circuit breakers 210 can be a non-smart function circuit breaker that needs to be manually operated and/or receive manual input.

Main sensors 202 are provided to sense one or more electrical characteristics of line power in line cables 204. In the example shown, main sensors 202 are transformers that sense current in line cables 204. Main sensors 202 output measurements that correspond to the sensed electrical characteristics and provide the measurements as measurement data via measurement cables 206 to edge device 111. Analog data can be converted to digital data at any of main sensors 202, edge device 111, and disaggregation monitor 101. Disaggregation monitor 101 can perform disaggregation by analyzing the measurement data corresponding to isolated branches 114, 116, 118 and loads 103a, b, c, d, e, f, g, h, i, 104a, b, c, d, 105a, b, c, d, e, f, g, h, i, j, 107a, b, c, d, e, f, g, h, i, j, k.

Edge device 111 can receive power via power cables 208 or from a different power source, such as a battery. Edge device 111 can further communicate wirelessly via antenna 212 and/or via wired network interface 214. Disaggregation monitor 101 can interface with each of antenna 212 and network interface 214 for communicating with external devices by wired and/or wireless communication. Disaggregation monitor 101 can communicate with one or more of its remote processing devices, such as to transmit measurement data received from main sensors 204 and state of connection data. The remote processing device(s) can perform disaggregation analysis as a function of the measurement data for isolated branches 114, 116, 118 and loads 103a, b, c, d, e, f, g, h, i, 104a, b, c, d, 105a, b, c, d, e, f, g, h, i, j, 107a, b, c, d, e, f, g, h, i, j, k as they are updated over time.

Since processing devices of disaggregation monitor 101 can be disposed in one or more locations, one or more processing devices of disaggregation monitor 101 can be integrated with or operatively coupled (e.g., via antenna 212 and/or network interface 214 of edge device 111) to receive measurement data from main sensors 202 and/or to communicate with branch circuit breakers 210 for controlling branch circuit breakers 210, for controlling loads connected to branch circuit breakers 210, and/or for receiving measurement data and/or results of analyzing the measurement data from branch circuit breakers 210. One or more processing devices of disaggregation monitor 101 can be disposed in the cloud.

The processing devices can communicate with one or more controllable loads, e.g., to turn them ON or OFF, to communicate with computational resources and sensors integrated with and/or coupled with the controllable loads that can provide control and/or measurement data and or results of analyzing the measurement data that can assist with the disaggregation process. Additionally, the processing devices of aggregation monitor 101 can communicate with a user interface, e.g., via user device 240, to give instructions to the user to perform actions during the automated control process, which can use an automated control mode tor an automated manual assist mode. The automated control mode instructs the user to provide user assistance at the beginning of the control process for turning on uncontrollable devices, followed by full automation of the controllable devices. The automated manual assist mode instructs the user to provide user assistance at different stages of the control process.

The automated manual assist mode can be useful in certain circumstances when operating in the learning phase. For example, disaggregation monitor 101 may benefit from using an automated manual assist mode to manage isolating certain loads that were not or would not be properly disaggregated using the automated control mode and/or to complete the circuit mapping. Examples of loads that may not be properly disaggregated using the automated control mode include non-controllable loads (which can include, for example, loads 104a-d, 105a-j), transient loads, seldom used loads, complex loads, low power loads or synchronized loads, and loads that do not turn ON when power is applied to the load.

Transient loads are loads that move or are moved between locations and can show up on many branches in circuit 120. Examples of transient loads include vacuum cleaners, power tools, phone chargers, and the like. Complex loads are loads that include several internal loads having different load types to create a functioning appliance. Examples of complex loads include clothes washers, dish washers, refrigerators, and the like. Complex loads may have resistive elements, motors, controls and other elements that are fundamental loads, which can make it difficult for the disaggregation process to recognize and obtain measurement data for the complex load in its entirety. The disaggregation may only recognize such fundamental loads inside a complex load and not attribute a correct amount of measurement data to the complex load.

Low power loads can be challenging to disaggregate, as these loads are typically included in another category that consumes a large percentage of total reported energy usage (such as a category of loads that are always ON). Synchronized loads are loads that turn ON at the same time using the automated control mode or the manual assist mode. This could include several lights attached to the same switched plugs or an automated system for operating lights or other loads, which can be a challenge when using disaggregation methods attempt to recognize each individual load.

Some loads, such as TVs, radios, coffer makers, printers, hand tools and the like, do not turn ON when power is applied. It would not be possible to disaggregate these loads without manually turning them ON. Also, some loads are used so infrequently that disaggregation methods may not recognize them because of the limited amount of operational time in a given timeframe for obtaining relevant measurement data for learning electrical characteristics associated with loads that do not turn ON when power is applied.

The automated manual assist mode can be used by the disaggregation monitor 101 to learn individual loads of the plurality of loads 103a-i, 104a-d, 105a-j through an interactive process with a user. During the automated manual assist mode, disaggregation monitor 101 can automatically provide user instructions to the user to guide the user how to assist. The disaggregation monitor 101 can use the circuit mapping to guide the user to manipulate loads (e.g., of loads 103a-i, 104a-d, 105a-j) on a particular branch (e.g. of branches 114, 116, 118) of circuit 120 in an iterative manner to ensure that loads are isolated by being turned on one at a time for each iteration.

The automated manual assist mode can be used, for example, after performance using the automated control mode. This may arise in situation in which all controllable loads (e.g., of controllable loads 103a-i) on a particular branch (e.g., of branches 114, 116, 118) have been isolated and an analysis was performed to identify power consumed by each of the isolated loads and disaggregate the isolated loads. However, following disaggregation of all of the isolated controllable loads, if it is still indicated that there is power being consumed that is not attributed to the controllable loads that have already been disaggregated (and optionally classified). It would be undesirable to lump this power (referred to as unattributed power) to a default category, such as “other” or “always on.” It would be further undesirable to lump together the default category for all branches into the same default category.

Rather, the automated manual assist mode can be used to isolate non-controllable loads (e.g., of 104a-d and 105a-j) connected to the branch and perform additional disaggregation to purposefully attribute the unattributed power to particular non-controllable loads (and not to a default group). Disaggregation monitor 101 can be configured to automatically interact with the user in real time to instruct the user turn on one non-controllable load at a time while monitoring power consumption and other electrical parameters. If there is a jump in power consumption when the isolated non-controllable load is turned on, and conversely if there is a drop in power consumption when the non-controllable load is turned off, this change in power consumption can be attributed to the load that is isolated and turned on or off. The user can be automatically instructed to turn on and off the load while all controllable loads connected to the branch are turned off such that the load is isolated or is as isolated as possible under the circumstances.

In this manner disaggregation monitor 101 can guide the user to turn loads on one at a time in the learning process. Once a load is learned disaggregation monitor 101 can prompt the user to enter additional information about the individual loads, such as make, model number, and/or location (e.g., identification of a room in a building). Disaggregation monitor 101 may further prompt the user for information about controllable loads that were previously disaggregated to further refine the database and provide a richer mapping with detailed load information (e.g., circuit location, load location, whether the load is controllable or not, etc.). The mapping can be rendered graphically, e.g., using a home layout, such as for display on a computer, tablet, mobile phone, or other smart device. This mapping can assist user or technician interactions to manage load malfunction, alarms, circuit faults, etc.

In one example, disaggregation monitor 101 would use measurement data obtained while isolating loads while in the manual mode to cluster multiple loads included in a complex load into the same load, such as using the following example method. Disaggregation monitor 101 can first disaggregate sub-loads within a complex load as separate sub-loads having fundamental classifications. For example disaggregation monitor 101 may disaggregate a first sub-load classified with a fundamental classification of pump (referred to as the pump sub-load) and assign the pump sub-load to a load that was disaggregated and classified with an appliance application of hot tub (referred to as the hot tub load) by applying knowledge about hot tub loads and its sub-loads. The hot tub load may also have a heater sub-load, but a sub-load has not yet been disaggregated or classified as a heater sub-load, and further has not been attributed to the hot tub load. Therefore, disaggregation monitor 101 has not determined an appropriate power consumption for the disaggregated hot tub load.

The automated control and manual assist modes can be used to detect the heater sub-load by observing power consumption while the user is automatically instructed to operate the hot tub load in different operating modes, possibly while the hot tub load is isolated. Disaggregation monitor 101 can use observations about the power consumption while the hot tub load is operated in the different operating modes to attribute both the pump sub-load and the heater sub-load to the hot tub load. Disaggregation monitor 101 can detect and use timing factors associated with the power consumption attributable to the pump and heater sub-loads, or other interactions between the pump and heater sub-loads in the time domain, which indicates a relationship between these sub-loads. For example, when the hot tub load calls for heat, it may first turn on the pump sub-load followed by turning on of the heater sub-load within 3 seconds. This temporal association can assist with determining that detected sub-loads classified by fundamental load types are associated with a load classified with an appropriate appliance load type.

In another example, disaggregation monitor 101 would be able to distinguish individual low power loads by instructing the user to plug in and turn ON transient loads at different operating states (e.g., high and low settings) and/or at different locations of the electrical circuit (e.g., by plugging it into an outlet in the living room and turning it ON, and then plugging it into an outlet of the kitchen and turning it ON. In this way, disaggregation monitor 101 would know that a transient load is being turned ON and its electrical signature from the measurement data obtained at the different operating states and/or locations. The disaggregation monitor 101 would classify any load detected on any branch circuit (e.g., branches 114, 116, 118) in the future that is associated with that electrical signature as a transient load. Disaggregation monitor 101 can instruct the user to operate two or more synchronized loads independently and then concurrently to obtain measurement data for each scenario. The measurement data obtained for each of these scenarios can be used to provide a more complete understanding of electrical characteristics of the two or more synchronized loads and learning their respective electrical signatures.

Performance using the automated control mode can be followed by performance using the automated manual assist process. The automated manual assist process can fill in missing information in the circuit mapping, with a very high percentage of loads on circuit 120 (e.g., loads 103a-i, 104a-d, 105a-j) disaggregated and mapped. The circuit mapping can include a list or pictorial representation of disaggregated loads, each load having an associated identification number (ID), its location within circuit 120, and its load type. For example, a pictorial representation of circuit 120 for a home can which circuits feed each of a bedroom, kitchen, family room, which loads are in each of the rooms, where the outlets are located on circuit 120 for each room, which loads are controlled by the outlets, and a location of each controllable load (e.g., of loads 103a-i) are in the room. The circuit mapping can then be used by a home monitoring system, such as for monitoring power usage, efficiency, and diagnosing problems.

Table 1 shows a portion of an example mapping that indicates for individual loads in the table a corresponding description of the load, a room in which the load is located, a branch number and name that identifies the branch to which the branch is connected, and a make and model number.

TABLE 1

| | | Branch | | |
|---|---|---|---|---|
| Room | Load | Number | Branch Name | Make |
| Master | Samsung^{(R)} TV | 1 | Master Bedroom Outlets | ABC1 |
| Bedroom | Lamp 1 | 1 | Master Bedroom Outlets | ABC2 |
| | Lamp 2 | 1 | Master Bedroom Outlets | ABC3 |
| | Heated Blanket | 1 | Master Bedroom Outlets | ABC4 |
| | Denon^{(R)} Stereo | 1 | Master Bedroom Outlets | ABC5 |
| | Ceiling fan | 2 | Master Bedroom and Master Bath | ABC6 |
| | | | Lights/outlets | |
| Mater | Curling iron | 2 | Master Bedroom and Master Bath | ABC7 |
| Bath | | | Lights/outlets | |
| | Ceiling lights | 2 | Master Bedroom and Master Bath | ABC8 |
| | | | Lights/outlets | |
| | Exhaust Fan | 2 | Master Bedroom and Master Bath | ABC9 |
| | | | Lights/outlets | |
| Kitchen | Microwave | 3 | Microwave | ABC10 |
| | Range | 8 | Range | ABC11 |
| | Dish washer | 5 | Garbage disposal/dishwasher | ABC12 |
| | Garbage disposal | 5 | Garbage disposal/dishwasher | ABC13 |
| | Refrigerator | 4 | Refrigerator | ABC14 |
| | Electric can opener | 6 | Small Appliance 1 | ABC15 |
| | Electric skillet | 7 | Small appliance 2 | ABC16 |

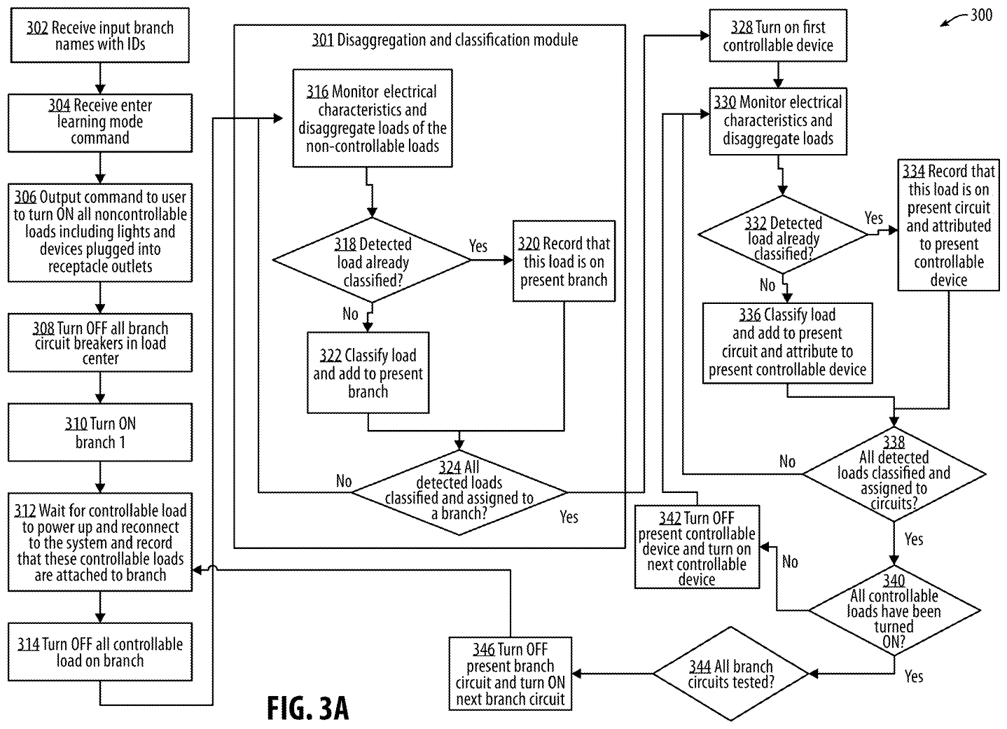

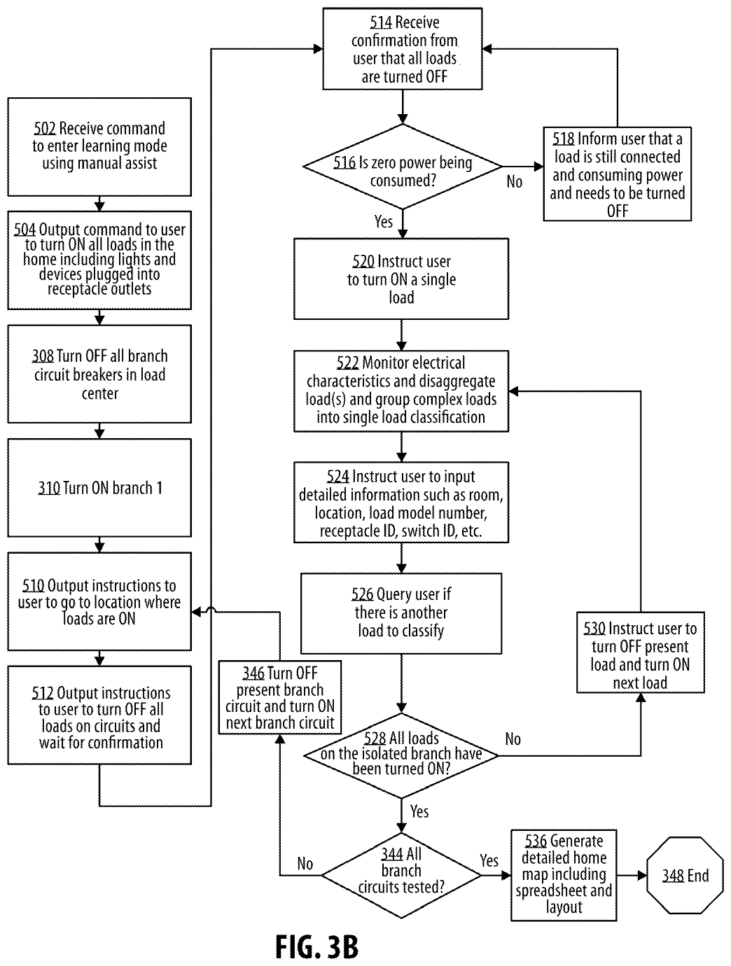

FIGS. 3A and 3B show exemplary and non-limiting flowcharts illustrating methods related to disaggregation of loads in an electrical power system, in accordance with certain illustrated embodiments. Before turning to the description of FIGS. 3A and 3B, it is noted that the flowcharts in FIGS. 3A and 3B show examples in which operational blocks are carried out in a particular order, as indicated by the lines connecting the blocks, but the various blocks shown in these flowcharts can be performed in a different order, or in a different combination or sub-combination. It should be appreciated that in some embodiments some of the blocks described below may be combined into a single block. In some embodiments, one or more additional blocks may be included. In some embodiments, one or more of the blocks can be omitted.

With reference to FIG. 3A, flowchart 300 shows an example method of fully automatically disaggregating controllable loads of a complex electrical circuit, such as loads 103a-i of electrical circuit 120 of electrical power system 100 shown in FIG. 1. The electrical circuit is coupled to a load center having main and branch circuit breakers that control provision of power to the entire electrical circuit and its branches, respectively. The method can be performed by a disaggregation monitor communicatively coupled to the electrical circuit and the load center, such as disaggregation monitor 101 shown in FIG. 1. This process is referred as “fully automatic” because it does not include instructions to a user other than at block 306 provided before full control of the circuit is enacted.

At block 302, in preparation of performing the disaggregation process, branch names are received with ID numbers for each branch of a plurality of branches of the electrical circuit (such as branches 114, 116, 118 shown in FIG. 1). The branch names and IDs are used to generate a circuit mapping of the electrical circuit. Block 302 is performed once before the first time the disaggregation process if performed (in fully automatic mode (also referred to as the automated control mode) or manual-assist mode). Block 302 can be performed again to update the branch names and ID numbers if the branches have been reconfigured. At block 304, a command is received to enter learning mode. The command can be input by a user or a processing device. At 306, an instruction is output to the user to turn ON all non-controllable loads in the home. The non-controllable loads can include, for example, lights and devices that are plugged into receptacle outlets that are not capable of connecting to a network or otherwise communicating with other devices. The non-controllable loads are turned ON before controlling the branches or controllable loads since the automated process cannot control the non-controllable loads, and in order that the non-controllable loads connected to each branch be ON during isolation of that branch. In this way, as the disaggregation monitor isolates a controllable load, the disaggregation monitor will sense power consumed for the isolated controllable load in addition to any non-controllable loads on the same branch and the branch's controllable circuit breaker located in the load center.

At block 308, all branch circuit breakers in load center are turned OFF, which allows individual branches to be turned ON one at a time so that they can be isolated. At block 310, a first branch (or branch set, referred to subsequently as branch) of the plurality of branches of the electrical circuit is turned ON. Turning ON this branch can be performed by automatically operating the associated branch circuit breaker. At block 312, a wait state is entered to wait for any controllable loads that connected to the currently isolated branch to power up and reconnect for establishing communication with the disaggregation monitor. Once communication is reestablished, these controllable loads are recorded as being connected to the currently isolated branch. This causes the controllable loads that are now powered up and have established communication to be mapped to the circuit mapping.

At block 314, all controllable loads on all of the branches are turned OFF. This will cause the controllable loads that were just mapped to the presently isolated branch to be turned OFF, while all other controllable loads remain OFF. This allows the controllable loads mapped to the presently isolated branch to be isolated one at a time relative to the other controllable loads of the electrical circuit, starting at block 315, albeit in the presence of any non-controllable loads connected to the same branch that are presently turned ON.

Blocks 316, 318, 320, 322, and 324 form a first inner loop of flowchart 300 that belongs to a disaggregation and classifier process for disaggregating and classifying the non-controllable loads and the controllable circuit breaker of the same branch, which are presently turned ON. At block 316, a monitoring process is performed to monitor electrical characteristics sensed on the branch and disaggregate loads of the non-controllable loads.

At block 318, a determination is made whether the load detected by disaggregation has already been classified. If the determination at block 318 is YES, meaning the detected load has already been classified, at block 320, the circuit mapping is updated to indicate that the detected load as previously classified belongs to the isolated branch. If the determination at block 318 is NO, meaning the detected load has not yet been classified, at block 322, the circuit mapping classifies the load and updates the circuit mapping to indicate that the detected load as now classified belongs to the isolated branch. At block 324, a determination is made whether all non-controllable loads detected on the isolated branch have been classified and added to the isolated branch in the circuit mapping.

If the determination at block 324 is NO, meaning all non-controllable loads on the isolated branch have not yet been classified and added to the circuit mapping, the method continues at block 316. The first inner loop flowchart 300 disaggregates the non-controllable loads in the presence of other non-controllable loads, continuing to iteratively disaggregate these non-controllable loads until it is determined that all the non-controllable loads that are currently turned ON are accounted for (e.g., classified and added to the circuit mapping). If the determination at block 324 is YES, meaning all non-controllable loads on the isolated branch have been accounted for, the method continues at block 328.

Steps 328-342 show how to sequence through turning the controllable loads ON one at a time to continue the disaggregation process. Although the non-controllable loads (and associated controllable circuit breaker) are still ON, automatic isolation of the branches and their controllable loads minimizes a number of loads ON at the same time on each isolated branch. At block 328, a first controllable load of the isolated branch is turned ON. The controllable load that is turned ON is referred to as the present controllable load. The present controllable load is effectually isolated, since all other controllable loads are turned OFF, and electrical characteristics for the non-controllable loads that remained ON were determined in the first inner loop of flowchart 300. Hence, the electrical characteristics for the non-controllable loads that remained ON can be subtracted or otherwise removed from electrical characteristics of the present controllable load. This effectual isolation can be treated as an actual isolation.

At block 330, electrical characteristics sensed on the isolated branch are monitored and the present controllable load is disaggregated. At block 332, a determination is made whether a load detected by the disaggregation has already been classified. If the determination at block 332 is YES, meaning the detected load has already been classified, at block 334, the detected load is recorded as being connected to the isolated present branch and is attributed to the present controllable load. If the determination at block 332 is NO, meaning the detected load has not yet been classified, at block 336, the circuit mapping is updated with classification of the detected load and an indication that the detected load belongs to the isolated branch and is attributed to the present controllable load.

At block 338, a determination is made whether all loads detected on the isolated branch by disaggregation of the present controllable load have been classified and added to the isolated branch, such as by updating the circuit mapping. Blocks 332, 334, 336, and 338 form a second inner loop flowchart 300 that can be used to iteratively disaggregate all loads attributable to the present controllable load. For example, if the present controllable load is a switch, outlet, or receptacle to which additional loads are connected, each of the additional loads can be disaggregated and attributed to the present controllable load. In another example, if the present controllable load is a complex load, its sub-loads can be disaggregated and attributed to the present controllable load. If the determination at block 338 is NO, meaning there are more loads associated with the present controllable load to be detected, the method continues at block 330. If the determination at block 338 is YES, meaning there are no further loads associated with the present controllable load to be detected or disaggregated, the method continues at block 340.

At block 340, a determination is made whether all controllable devices on the isolated branch have been turned ON. Blocks 332, 334, 336, and 338, 340, and 342 form a third inner loop of flowchart 300 that can be used to iteratively turn ON, one at a time, each controllable load connected to the isolated branch. If the determination at block 340 is NO, meaning there are more controllable loads connected to the isolated branch that still need to be turned ON, the method continues at block 342. At block 342, the present controllable device is turned OFF and a next controllable load is turned ON, after which the method continues at block ee0 with the next controllable load treated as the present controllable load during the next iteration of the second and third inner loops. If the determination at block 340 is YES, meaning all of the controllable loads connected to the isolated branch have been turned ON, the method continues at block 344.

At block 344, at determination is made whether all of the branches have been isolated and tested. Blocks 340, 344, 346, 312, 314, and 316 form an outer loop of flowchart 300, which includes the first, second, and third inner loops. The outer loop is used to turn on the branches one at a time for isolating a different branch each time the outer loop is iterated. If the determination at block 344 is YES, meaning that all of the branches have been isolated and tested, then the method ends at block 348. A home map can be generated before ending the method. The home map can include, for example, a spreadsheet and/or a graphical layout of the electrical circuit, including its loads and branches, relative to a structure of the building in which it resides. If the determination at block 344 is NO, meaning that there are more branches to be isolated and tested, then the method continues at block 346 at which the branch that is presently isolated and turned on is turned OFF, and a next branch is selected to be isolated and turned ON while all of the other branches remain turned OFF. The method continues at block 312 to test controllable loads on the branch that was newly selected to be isolated and is now turned ON.

With reference to FIG. 3B, flowchart 500 shows an example method of automatically disaggregating controllable loads of a complex electrical circuit, similar to FIG. 3A, using automated recommendations for manual assistance. The method can be performed by a disaggregation monitor communicatively coupled to the electrical circuit and the load center, such as disaggregation monitor 101 shown in FIG. 1 when operating in the manual assist mode. Some blocks of flowchart 500 are identified by the same reference numerals as used for blocks in FIG. 3A. When the corresponding blocks in FIGS. 3A and 3B have the same reference numeral, they are substantially the same. It is assumed that block 302 has been previously performed.

At block 502, a command is received to enter the learning mode using manual-assist. The command can be input by a user or a processing device. At block 504, an instruction is output to the user to turn ON all loads in the home, including lights and devices plugged into receptacle outlets.

At block 308, all branch circuit breakers in load center are turned OFF, which allows individual branches to be turned ON one at a time so that they can be isolated. At block 310, a first branch (or branch set, referred to subsequently as branch) of the plurality of branches of the electrical circuit is turned ON. Turning ON this branch can be performed by automatically operating the associated branch circuit breaker.

At block 510, instructions are output to the user to go to a location where the loads are located and are turned ON. At block 512, instructions are output to the user to turn OFF all of the loads on of the electrical circuit and a wait state is entered to wait for confirmation from the user that all loads were turned OFF. At block 514, confirmation is received from the user that all loads are turned OFF.

At block 516, a determination made whether zero power is being consumed by the loads. If the determination at block 516 is NO, meaning some power is being consumed by a load indicating that at least one load is turned ON, the method continues at block 518. At block 518, a message is sent to the user to inform the user that a load that is still connected to the electrical power system and is consuming power needs to be turned OFF. In certain scenarios, it may be determined that zero power is not attainable. Blocks 514, 516, and 518 form a first inner loop of flowchart 500 for assisting the user to know when all loads are turned OFF.

If the determination at block 516 is YES, meaning zero power is being consumed (or it has been determined that zero power is not attainable), the method continues at block 520. At block 520, an instruction is output to the user to turn ON a single load. This single load is isolated, as it is the only load that is turned ON. At block 522, electrical characteristics of the load that is turned ON are monitored. Electrical characteristics for any loads that remained ON (e.g., which caused zero load to be not attainable) can be identified and disregarded for analysis of the isolated load. Various algorithms that use logic, machine learning, etc., can analyze the electrical characteristics of the load and disaggregate the load. The disaggregation performed at block 522 can include determining an electrical signature of the isolated load for disaggregating and classifying the load, e.g., according to its fundamental load type or appliance load type.

In this way, the electrical signature of the isolated load can be disaggregated and classified as a single load, even when it is a complex load. If desired, components of the complex load can be analyzed and identified in an internal sub-loop (not shown) in which the load is iteratively operated in different loads and the electrical signature is analyzed at each iteration to identify, disaggregate, and classify separate components of the load.

At block 524, the user is instructed to input detailed information about the isolated load, such as room in which it is located, location within the room, load model number, receptacle ID, switch ID, etc. At block 526, a query is provided to the user whether there is another load on the isolated branch that hasn't been isolated and analyzed for disaggregation and classification. At block 528, a determination is made based on the user's response whether all loads on the isolated branch have been isolate and analyzed for disaggregation and classification.

If the determination at block 528 is NO, meaning there are more loads on the isolated branch to be isolated and analyzed for disaggregation and classification, the method continues at block 530. At block 530, the user is instructed to turn OFF the presently isolated load and turn ON a next load. The next load is thus isolated and becomes the presently isolated load at block 522. If the determination at block 528 is YES, meaning all of the loads on the isolated branch have been isolated and analyzed for disaggregation and classification, the method continues at block 344. Blocks 522, 524, 526, 528, and 530 form a second inner loop of flowchart 500 that is iterated for isolating each load of the presently isolated branch and analyzing its electrical characteristics for disaggregation and classification.

At block 344, a determination is made whether all of the branches have been isolated and tested. Blocks 340, 344, 346, 312, 314, and 316 form an outer loop of flowchart 500 which includes the first and second inner loops. The outer loop is used to turn on the branches one at a time for isolating a different branch each time the outer loop is iterated. If the determination at block 344 is YES, meaning that all of the branches have been isolated and tested, then the method continues at block 536. At block 536, a detailed home map can be generated that can include, for example, a spreadsheet and/or a graphical layout of the electrical circuit relative to a structure of the building in which it resides. The method ends at block 348.

If the determination at block 344 is NO, meaning that there are more branches to be isolated and tested, then the method continues at block 346 at which the branch that is presently isolated and turned on is turned OFF, and a next branch is selected to be isolated and turned ON while all of the other branches remain turned OFF. The method continues at block 510 to output instructions to the user to go to a location of a next load that needs to be turned ON. Thus the method continues until all loads on each branch have been analyzed for disaggregation and classification.

A combination of the methods shown in FIGS. 3A and 3B can be performed. For example, the manual assist mode shown in FIG. 3B can be used to perform the first inner loop of flowchart 300 of FIG. 3A. In another example, the user can choose to use the fully automatic mode for some branches and the manual assist mode for other branches. The disaggregation monitor can, based on how successful the fully automatic mode performed, recommend manual assist mode for some branches and not for others. This could be implemented, for example and without limitation, by recommending the manual assist mode for those branches that had a low rate of success (e.g., a rate of success score that is lower than a predetermined threshold, or for X percent of the branches having the lowest rate of success scores, where X is a configurable variable) using the fully automatic mode.

In the preceding, reference is made to various embodiments. However, the scope of the present disclosure is not limited to the specific described embodiments. Instead, any combination of the described features and elements, whether related to different embodiments or not, is contemplated to implement and practice contemplated embodiments. Furthermore, although embodiments may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

The various embodiments disclosed herein may be implemented as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer-readable medium(s) having computer-readable program code embodied thereon.

Any combination of one or more computer-readable medium(s) may be utilized. The computer-readable medium may be a non-transitory computer-readable medium. A non-transitory computer-readable medium may be, for example, but not limited to, an electronic, magnetic, optical, electromagnetic, infrared, or semiconductor system, apparatus, or device, or any suitable combination of the foregoing. More specific examples (a non-exhaustive list) of the non-transitory computer-readable medium can include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. Program code embodied on a computer-readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages. Moreover, such computer program code can execute using a single computer system or by multiple computer systems communicating with one another (e.g., using a local area network (LAN), wide area network (WAN), the Internet, etc.). While various features in the preceding are described with reference to flowchart illustrations and/or block diagrams, a person of ordinary skill in the art will understand that each block of the flowchart illustrations and/or block diagrams, as well as combinations of blocks in the flowchart illustrations and/or block diagrams, can be implemented by computer logic (e.g., computer program instructions, hardware logic, a combination of the two, etc.). Generally, computer program instructions may be provided to a processor(s) of a general-purpose computer, special-purpose computer, or other programmable data processing apparatus. Moreover, the execution of such computer program instructions using the processor(s) produces a machine that can carry out a function(s) or act(s) specified in the flowchart and/or block diagram block or blocks.

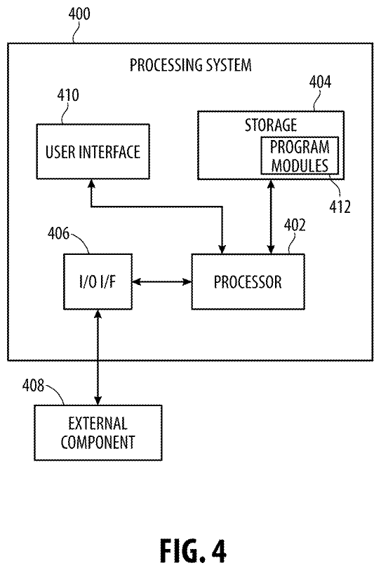

With reference to FIG. 4, a block diagram of an example computer system 400 is shown, which provides an example configuration of disaggregation monitor 101, which can be embodied, separately or in any combination, in one or more computer systems. One such computer system 400 is illustrated in FIG. 4. In various embodiments, computer system 400 may be a server, a mainframe computer system, a workstation, a network computer, a desktop computer, a laptop, a handheld computer, an embedded system, or the like, and/or include one or more of a processor, field-programmable gate array (FPGA), application specific integrated circuit (ASIC), microcontroller, microprocessor, or the like. Computer system 400 is only one example of a suitable system and is not intended to suggest any limitation as to the scope of use or functionality of embodiments of the disclosure described herein. Computer system 400 can be implemented using hardware, software, and/or firmware. Regardless, processing system 400 is capable of being implemented and/or performing functionality as set forth in the disclosure.

Computer system 400 is shown in the form of a general-purpose computing device. Computer system 400 includes one or more processors 402, storage 404, an input/output (I/O) interface (I/F) 406 that can communicate with an internal component, such as a user interface 410, and optionally an external component 408.

Disaggregation monitor 101 can be configured to handle large amounts of data. Computer system(s) used to implement disaggregation monitor 101 can be implemented, for example, using multiprocessors, a big data architecture, or one or more cloud-based computer systems.

The processor(s) 402 can include, for example, a single core or multicore processor, a programmable logic device (PLD), microprocessor, DSP, a microcontroller, an FPGA, an ASIC, and/or other discrete or integrated logic circuitry having similar processing capabilities.

The processor(s) 402 and the storage 404 can be included in components provided in the FPGA, ASIC, microcontroller, or microprocessor, for example. Storage 404 can include, for example, volatile and non-volatile memory for storing data temporarily or long term, and for storing programmable instructions executable by the processor(s) 402. Storage 404 can be a removable (e.g., portable) memory for storage of program instructions. I/O I/F 406 can include an interface and/or conductors to couple to the one or more internal components and/or external components 408.

The program instructions include program modules 412 for generally carrying out the functions and/or methodologies of embodiments of the disclosure as described herein, as well as an operating system, one or more application programs, other program modules, and program data. Each of the operating system, one or more application programs, other program modules, and program data or some combination thereof, may include an implementation of a networking environment.

The computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flow diagram and/or block diagram block or blocks.

The computer program instructions may also be loaded onto a computer, other programmable data processing apparatus, or other devices to cause a series of operational operations to be performed on the computer, other programmable apparatus or other devices to produce a computer implemented process. The instructions when executed on the computer or other programmable apparatus provide processes for implementing the disclosed functions/acts, including those specified in the block diagram block or blocks.

Embodiments of the processing components of disaggregation monitor 101 may be implemented or executed by one or more computer systems, such as a microprocessor. Each computer system 400 or multiple instances thereof can be included, for example, within edge device(s) 111, user device(s) 140, and cloud-based device(s) 150. The computer system 400 can be provided as an embedded device or include an embedded device. Portions of the computer system 400 can be provided externally, such by way of a virtual, centralized, and/or cloud-based computer.

Computer system 400 is only one example of a suitable system and is not intended to suggest any limitation as to the scope of use or functionality of embodiments of the disclosure described herein. Regardless, computer system 400 is capable of being implemented and/or performing any of the functionality set forth hereinabove.

Computer system 400 may be described in the general context of computer system-executable instructions, such as program modules, being executed by a computer system. Generally, program modules may include routines, programs, objects, components, logic, data structures, and so on that perform particular tasks or implement particular abstract data types.

The terms “comprises” or “comprising” are to be interpreted as specifying the presence of the stated features, integers, operations or components, but not precluding the presence of one or more other features, integers, operations or components or groups thereof.

Those having ordinary skill in the art understand that any numerical values disclosed herein can be exact values or can be values within a range. Further, any terms of approximation (e.g., “about”, “approximately”, “around”) used in this disclosure can mean the stated value within a range. For example, in certain embodiments, the range can be within (plus or minus) 20%, or within 10%, or within 5%, or within 2%, or within any other suitable percentage or number as appreciated by those having ordinary skill in the art (e.g., for known tolerance limits or error ranges).

The articles “a”, “an”, and “the” as used herein and in the appended claims are used herein to refer to one or to more than one (i.e., to at least one) of the grammatical object of the article unless the context clearly indicates otherwise. By way of example, “an element” means one element or more than one element.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.”

Potential advantages provided by the disclosed disaggregation process shown and described include an automated disaggregation process automatically isolates branches of an electrical circuit to obtain a reduced amount of data about electrical characteristics of loads connected to the branch for an improved understanding of the individual loads. In addition, in the automated process, loads can be automatically isolated by automatic control or instructions automatically provided to a user to manually assist and/or to confirm classification decisions. Furthermore, additional attention can be automatically provided for detecting loads that were not yet successfully or correctly disaggregated. Additional automated isolation processes can be performed to disaggregate complex, synchronized, and transient loads.

The techniques described herein are exemplary, and should not be construed as implying any particular limitation of the certain illustrated embodiments. It should be understood that various alternatives, combinations, and modifications could be devised by those skilled in the art. For example, operations associated with the processes described herein can be performed in any order, unless otherwise specified or dictated by the operations themselves. The present disclosure is intended to embrace all such alternatives, modifications and variances that fall within the scope of the appended claims.

The terms “comprises” or “comprising” are to be interpreted as specifying the presence of the stated features, integers, operations or components, but not precluding the presence of one or more other features, integers, operations or components or groups thereof.

In the preceding, reference is made to various embodiments. However, the scope of the present disclosure is not limited to the specific described embodiments. Instead, any combination of the described features and elements, whether related to different embodiments or not, is contemplated to implement and practice contemplated embodiments. Furthermore, although embodiments may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

The various embodiments disclosed herein may be implemented as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer-readable medium(s) having computer-readable program code embodied thereon.

Any combination of one or more computer-readable medium(s) may be utilized. The computer-readable medium may be a non-transitory computer-readable medium. A non-transitory computer-readable medium may be, for example, but not limited to, an electronic, magnetic, optical, electromagnetic, infrared, or semiconductor system, apparatus, or device, or any suitable combination of the foregoing. More specific examples (a non-exhaustive list) of the non-transitory computer-readable medium can include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. Program code embodied on a computer-readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages. Moreover, such computer program code can execute using a single computer system or by multiple computer systems communicating with one another (e.g., using a local area network (LAN), wide area network (WAN), the Internet, etc.).

The flowchart and block diagrams in the Figures illustrate the architecture, functionality and/or operation of possible implementations of various embodiments of the present disclosure. In this regard, each block in the flowchart or block diagrams may represent a module, segment or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

It is to be understood that the above description is intended to be illustrative, and not restrictive. Many other implementation examples are apparent upon reading and understanding the above description. Although the disclosure describes specific examples, it is recognized that the systems and methods of the disclosure are not limited to the examples described herein, but may be practiced with modifications within the scope of the appended claims. Accordingly, the specification and drawings are to be regarded in an illustrative sense rather than a restrictive sense. The scope of the disclosure should, therefore, be determined with reference to the appended claims, along with the full scope of equivalents to which such claims are entitled.

What is claimed is:

1. A disaggregation monitor of an electrical power system having an electrical circuit that includes a plurality of branches and a plurality of loads and, the disaggregation module comprising:
at least one memory configured to store instructions;
at least one processing device disposed at the location and in communication with the at least one memory, wherein the at least one processing device upon execution of the instructions is configured to:
a) iteratively and automatically control or instruct to turn ON one branch set having one or more branches of the plurality of branches at a time while remaining branches of the plurality of branches are turned OFF to isolate the branch set until all branches of the plurality of branches have been included in at least one isolated branch set;
b) obtain an electrical signature of each isolated branch set; and
c) disaggregate at least one load of the plurality of loads using two or more of the electrical signatures obtained.

2. The disaggregation monitor of claim 1, the at least one processing device upon execution of the instructions is further configured at a particular iteration of operation a) for a particular branch set that is isolated to:
d) iteratively and automatically control or instruct to turn ON one load set of a second plurality of loads connected to the particular branch set at a time while remaining loads of the plurality of loads on the particular branch set that can be turned OFF are turned OFF to isolate the load set until all loads of the second plurality of loads have been included in at least one isolated load set; and
e) obtain an electrical signature of each isolated load set,
wherein at operation c), the at least two different loads that are disaggregated include first and second loads of the second plurality of loads.

3. The disaggregation monitor of claim 2, wherein the particular branch set includes one branch and/or wherein the load set includes one load.

4. The disaggregation monitor of claim 1, wherein a particular iteration of operation a) is performed by automatically controlling to turn ON the isolated branch set and to turn OFF the remaining branches by controlling smart branch circuit breakers that correspond to respective branches of the plurality of branches.

5. The disaggregation monitor of claim 2, wherein the at least one processing device upon execution of the instructions is further configured at operations b) and/or e) to:
obtain measurements from main sensors sensing line inputs to a main circuit breaker for the electrical circuit; and/or
obtain measurements at the isolated load set.

6. The disaggregation monitor of claim 5, wherein the at least one processing device upon execution of the instructions is further configured at operations b) and/or e) to: analyze electrical characteristics obtained from the main sensors and/or receive analysis of measurements obtained at the isolated load set for obtaining the electrical signature of each isolated branch set and/or load set.

7. The disaggregation monitor of claim 2, wherein the at least one processing device upon execution of the instructions is further configured to use the electrical signatures of the isolated load sets to classify the respective isolated load sets.

8. The disaggregation monitor of claim 2, wherein the at least one processing device upon execution of the instructions is further configured to:
determine a location of the respective isolated load sets; and
add the respective isolated load sets to a circuit mapping based on the corresponding location determined respective for the respective isolated sets.

9. The disaggregation monitor of claim 2, wherein the at least one processing device upon execution of the instructions is further configured to operate one or more visual and/or audio indicators associated with one or more controllable loads of the second plurality of loads to provide a signal to a user regarding which load set of the electrical circuit is the isolated load set.

10. The disaggregation monitor of claim 2, wherein the at least one processing device upon execution of the instructions is further configured to:
identify one or more loads of the second plurality of loads that were not successfully isolated in any of the isolated load sets or for which a disaggregated electrical signature was not successfully obtained;
provide instructions to a user for manually isolating the respective identified one or more loads;
obtain disaggregated electrical signatures of the respective identified one or more loads after being manually isolated;
attempt to classify the respective identified one or more loads based on each identified load's corresponding disaggregated electrical signature;
determine a location of the respective identified one or more loads; and
add the respective identified one or more loads to a circuit mapping using results of the attempt to classify and the location.

11. The disaggregation monitor of claim 10, wherein the at least one processing device upon execution of the instructions is further configured to:
identify among the identified one or more loads a synchronized load; and
perform any combination of isolate, disaggregate, classify, and add to a circuit mapping individual loads included in the synchronized load.

12. The disaggregation monitor of claim 10, wherein the at least one processing device upon execution of the instructions is further configured to:
identify among the identified one or more loads multiple loads of the plurality loads that belong to one complex load; and
classify and/or add to a circuit mapping the multiple loads as belonging to the complex load.

13. The disaggregation monitor of claim 10, wherein the at least one processing device upon execution of the instructions is further configured to:
identify among the identified one or more loads a transient load;
instruct a user to turn ON the transient load by operating the transient load at different operating states and/or at different locations of the electrical circuit; and
obtain a disaggregated electrical signature of the transient load based on measurements obtained while operating the transient load at its different operating states and/or at the different locations.

14. A method of performing disaggregation to a plurality of loads connected to a plurality of branches included in an electrical power system, the method comprising:
iteratively and automatically controlling or instructing to turn ON one branch set having one or more branches of the plurality of branches at a time while remaining branches of the plurality of branches are turned OFF to isolate the branch set;
obtaining an electrical signature of each isolated branch set; and
disaggregating at least one load of the plurality of loads using two or more of the electrical signatures obtained.

15. The method of claim 14, wherein for a particular iteration of automatically controlling or instructing to turn ON a particular branch set when the particular branch set is isolated, the method further comprises;
Iteratively and automatically controlling or instructing to turn ON one load set of a second plurality of loads connected to the particular branch set at a time while remaining loads of the plurality of loads on the particular branch set that can be turned OFF are turned OFF to isolate the load set until all loads of the second plurality of loads have been included in at least one isolated load set; and
obtaining a load electrical signature of each isolated load set, wherein the at least two different loads that are disaggregated include first and second loads of the second plurality of loads.

16. The method of claim 15, wherein the method further comprises using the electrical signatures of the isolated load sets to classify the respective isolated load sets.

17. The method of claim 15, wherein the method further comprises:
determining a location of the respective isolated load sets; and
adding the respective isolated load sets to a circuit mapping based on the corresponding location determined respective for the respective isolated sets.

18. The method of claim 15, wherein the method further comprises operating one or more visual and/or audio indicators associated with one or more controllable loads of the second plurality of loads to provide a signal to a user regarding which load set of the electrical circuit is the isolated load set.

19. The method of claim 15, wherein the method further comprises:
identifying one or more loads of the second plurality of loads that were not successfully isolated in any of the isolated load sets or for which a disaggregated electrical signature was not successfully obtained;
providing instructions to a user for manually isolating the respective identified one or more loads;
obtaining disaggregated electrical signatures of the respective identified one or more loads after being manually isolated;
attempting to classify the respective identified one or more loads based on each identified load's corresponding disaggregated electrical signature;
determining a location of the respective identified one or more loads; and
adding the respective identified one or more loads to a circuit mapping using results of the attempt to classify and the location.

20. A non-transitory computer readable medium having computer executable instructions configured to cause a computer to perform a method, the method comprising:
Iteratively and automatically controlling or instructing to turn ON one branch set having one or more branches of the plurality of branches at a time while remaining branches of the plurality of branches are turned OFF to isolate the branch set;
obtaining an electrical signature of each isolated branch set; and
disaggregating at least one load of the plurality of loads using two or more of the electrical signatures obtained;
wherein for a particular iteration of automatically controlling or instructing to turn ON a particular branch set when the particular branch set is isolated, the method further comprises:
iteratively and automatically controlling or instructing to turn ON one load set of a second plurality of loads connected to the particular branch set at a time while remaining loads of the plurality of loads on the particular branch set that can be turned OFF are turned OFF to isolate the load set until all loads of the second plurality of loads have been included in at least one isolated load set; and
obtaining an electrical signature of each isolated load set wherein the at least two different loads that are disaggregated include first and second loads of the second plurality of loads.
